(19) United States
(12) Patent Application Publication
(10) Pub. No.: US 2003/0162351 A1
(43) Pub. Date: Aug. 28, 2003

(54) Oxidation resistane structure for metal insulator metal capacitor

(75) Inventor: Jason Jyh-Shyang Jenq, Ping-Tung City (TW)

Correspondence Address: MERCHANT & GOULD PC, P.O. BOX 2903, MINNEAPOLIS, MN, 55402-0903, US

(73) Assignee: United Microelectronics Corp., Hsin-Chu City (TW)

(21) Appl. No.: 10/084,392

(22) Filed: Feb. 25, 2002

(51) Int. Cl. H01L 21/8242

(52) U.S. Cl. 438/239

(57) ABSTRACT

A method for forming an oxidation-resistant structure for a MIM (metal-insulator-metal) capacitor is disclosed. The method is provided an oxidation-resistant barrier layer such as TaN is deposited by reactive sputtering method in the node-contact hole opening within a first ILD (inter layer dielectric) layer on the substrate. The method is also provided a first electrode plate (bottom electrode) such as Ta—Ru—N layer that has good oxygen diffusion barrier, good thermal stability, and low resistivity, is deposited on the storage-node (SN) hole opening. Further, the dielectric layer with high dielectric constant is between the first electrode and second electrode (upper electrode) to increase the capacitance of the MIM capacitor.

### BACKGROUND OF THE INVENTION

1. Field of the Invention

The present invention generally relates to a method for forming a MIM (metal-insulator-metal) capacitor in a DRAMs (dynamic random access memory) device, and more particularly to a method for forming an oxidation-resistance structure for MIM capacitor.

2. Description of the Prior Art

Presently, there is a great demand for shrinking semiconductor devices to provide an increased density of devices on the semiconductor chip that are faster and consume less power. The scaling of devices in the lateral dimension requires vertical scaling as well so as to achieve adequate device performance. The vertical scaling requires the effective electrical thickness of the gate dielectric to reduce so as to provide the required device performance.

Referring to FIG. 1, a conventional DRAMs (dynamic random access memory) device includes a MIM-Ta₂O₅ (metal-insulator-metal tantalum pentoxide) capacitor structure and a MOS (metal oxide semiconductor) transistor, wherein the MOS transistor adjacents the MIM-Ta₂O₅ capacitor structure. The MOS transistor structure includes a gate electrode (include a pad oxide layer 102 on the substrate 100 and a poly gate 104 on the pad oxide layer 102), an LDD (lightly doped drain) region 106 below the gate electrode, an S/D (source/drain) region 108 adjacents the LDD region 106 in a substrate 100, and a spacer 110 on the sidewall of the gate electrode. Then, a node contact hole formed within an ILD (inter-layer dielectric) layer 120, a polysilicon 122 formed n the node contact hole opening, and a barrier metal layer 124 formed on the polysilicon 122. The MIM-Ta₂O₅ includes a bottom electrode plate such as Ru (ruthenium) 126, an insulator layer such as Ta₂O₅ 128 on the sidewall of the bottom electrode 126, and a top electrode such as TaN (tantalum nitride) or TiN (titanium nitride) 130 on the insulator layer 128.

The conventional MIM capacitor comprises a first electrode (metal) 126, an insulator layer 128 such as Ta₂O₅, and a second electrode (Ru (ruthenium)) 130 is the most provided popular structure in giga-bit DRAMs with design rules of 0.1 μm and below. Fabricating the MIM-Ta₂O₅ capacitor needs the oxidizing process at temperature higher than 550° C. to increase the dielectric constant by the oxystabilization of Ta₂O₅. Therefore, during the oxidation process, oxygen ions diffuse through the Ru storage-node (SN) electrode, and oxidize the barrier metal layer 124 beneath SN. A typical barrier metal layer 124, TiN, was oxidized and N₂ bubbles were produced after the oxidation at 600° C. Furthermore, there is no visible change at low-temperature oxidation at 500° C. However, the MIMs depth profile revealed that the diffused oxygen ions are accumulated at the TiN temperature. Such as oxidation increased the contact resistance, and thus the DRAM high-speed operations will be failed.

### SUMMARY OF THE INVENTION

It is an object of this invention to form a MIM (metal-insulator-metal) capacitor structure in a DRAM (dynamic random access memory) device.

It is another object of this invention to form an oxidation-resistant structure for a MIM capacitor structure.

It is a further object of this invention to provide a good oxygen diffusion barrier layer to prevent the oxygen ions from diffusing through the bottom electrode of MIM capacitor and oxidize the diffusion barrier layer.

It is still another object of this invention to provide a dielectric layer with high dielectric constant to increase the capacitance and coupling ratio for the MIM capacitor.

According to abovementioned objects, the present invention is to provide a diffusion barrier layer to prevent the oxygen ions through the bottom electrode of MIM capacitor and oxidize the barrier metal layer. The forming step of the present invention is to form a first ILD (inter-layer dielectric) layer and SiN (silicon nitride) layer on the substrate, wherein the substrate has a gate structure thereon, a spacer on sidewall of the gate structure, a LDD (lightly doped drain) region below the gate structure and in the substrate, and a S/D (source/drain) region adjacent the LDD region in the substrate. Then, a node-contact hole opening is formed by etching process. Next, a polysilicon layer is deposited to fill with the node-contact hole opening by a conventional chemical vapor deposition method. Thereafter, an etching back process is performed to etch the polysilicon and recessed polysilicon, such that the polysiliocn is recessed in the node-contact hole. Then, the diffusion barriers layer such as TaN (tantalum nitride) layer is formed on the recessed polysilicon, and plaranized by CMP (chemical mechanical polishing) method. Next, second ILD layer is deposited and a storage node (SN) hole opening is formed within the second ILD layer.

It is an important feature of the present invention for forming a first metal layer such as Ta—Ruₓ—N_{y} (tantalum-ruthenium-nitrogen) layer as first electrode of MIM capacitor in the storage node hole opening by CVD (chemical vapor deposition) method, wherein the suffix x and y are represent the stoichiometry for Ru and N respectively. Then, an etching back process is performed to Ta—Ruₓ—N_{y} layer to form on the sidewall of the SN hole opening. It is still key of the present invention is to form an insulator layer such as a dielectric layer with a high dielectric constant such as Al (aluminum) doped Zr (zirconium)-silicate on the Ta—Ru—N layer, after the second ILD layer is removed. It is still an important feature of the present invention, in order to crystallization for insulator layer, an annealing process at about 550° C. on the dielectric layer. Then, a TaN layer or TiN (titanium nitride) layer is deposited to fill with the SN hole opening to form a top electrode of the MIM-capacitor.

The advantage of the Ta—Ruₓ—N_{y} has a good thermal stability and oxygen diffusion barrier when the value of suffix x is 1.0, y is between 0.4 and 0.6. Furthermore, the TaNₓ layer is an excellent oxygen diffusion barrier layer that can prevent the oxygen ions through the bottom electrode of the MIM capacitor to the barrier metal to cause the oxidation of barrier metal. When the value of suffix x is between 0.45 and 0.55, the TaNₓ has an excellent barrier property.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is a schematic representation showing a conventional MIM-Ta₂O₅ (metal-insulator-metal tantalum pentoxide) capacitor in DRAMs (dynamic random access memory).

FIG. 2 is a schematic representation showing a first ILD (inter-layer dielectric) layer and a SiN (silicon nitride) layer formed on the substrate in accordance with a method disclosed herein;

FIG. 3 is a schematic representation showing a node-contact hole opening within the structure of the FIG. 2, and a polysilicon and a barrier metal in the node-contact hole opening in accordance with a method disclosed herein;

FIG. 4 is a schematic representation showing a second ILD layer on the structure of the FIG. 3 in accordance with a method disclosed herein;

FIG. 5 is a representation showing a storage node (SN) hole opening formed within the structure of the FIG. 4 in accordance with a method disclosed herein;

FIG. 6 is a representation showing a bottom electrode plate of the MIM capacitor structure formed on sidewall of the storage node hole opening in accordance with a method disclosed herein; and

FIG. 7 is a representation showing a dielectric layer with a high dielectric constant and a top electrode plate of the MIM capacitor formed on the structure of the FIG. 6 in accordance with a method disclosed herein.

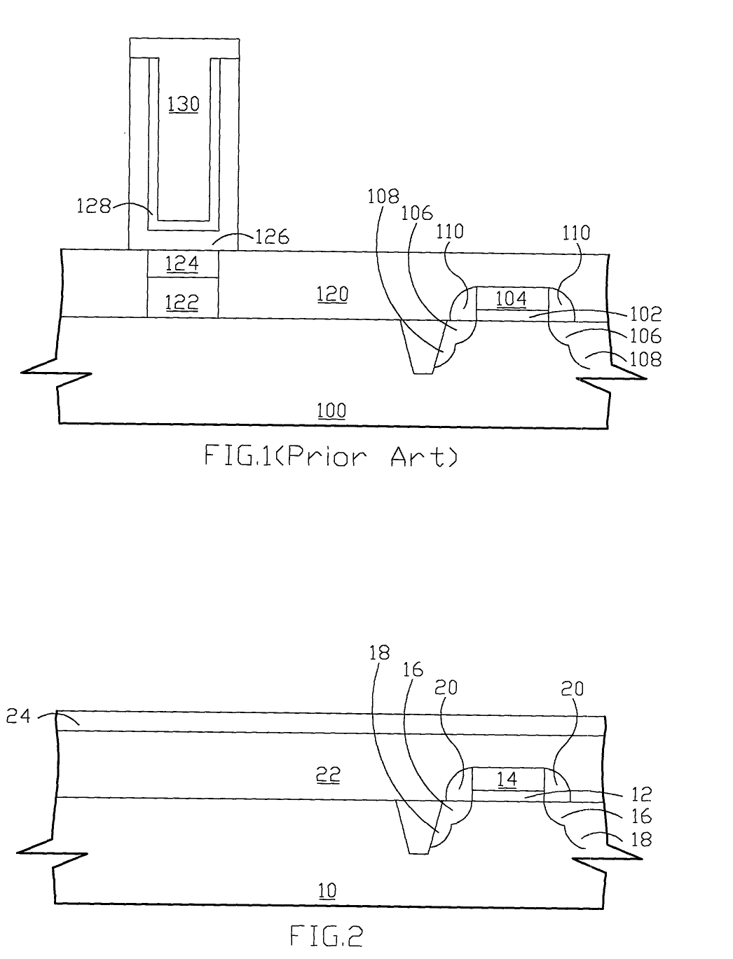

### DESCRIPTION OF THE PREFERRED EMBODIMENT

Some sample embodiments of the invention will now be described in greater detail. Nevertheless, it should be recognized that the present invention can be practiced in a wide range of other embodiments besides those explicitly described, and the scope of the present invention is expressly not limited except as specified in the accompanying claims.

According to the disadvantage for the conventional MIM-Ta₂O₅ (metal-insulator-metal tantalum pentoxide) capacitor such as the oxygen ions will diffuse through the bottom electrode (Ru (ruthenium) electrode) during the oxidation process and also oxidize the barrier metal layer that the capacitance of the MIM capacitor will be reduced, the node resistance will be increased, and the device reliability will be reduced. For this reason, the present invention provides a method to prevent the oxygen ions from diffusing through bottom electrode and oxidizes the barrier metal layer. The present invention provides an oxidation-resistant barrier metal layer consisting of TaN that revealed an excellent barrier performance such that the oxygen ions will not through the bottom electrode plate and oxidizes the barrier metal layer.

Referring to FIG. 2, a MOS (metal-oxide-semiconductor) transistor is first formed on a substrate 10. The MOS transistor includes a gate electrode (include a pad oxide layer 12 and a poly gate 14) on the substrate 10, an LDD (lightly doped drain) region 106 in the substrate 100 an S/D (source/drain) region 18 adjacent the LDD region 16 in the substrate 10, and a spacer 20 on the sidewall of the gate electrode. In addition, the isolation structure can be STI (shallow trench isolation) or FOX (field oxide region) to isolate transistor and capacitor in the substrate 10. Then, a first ILD (inter-layer dielectric) layer 22 and a SiN (silicon nitride) layer 24 are sequentially formed on the substrate 10 and cover the MOS transistor.

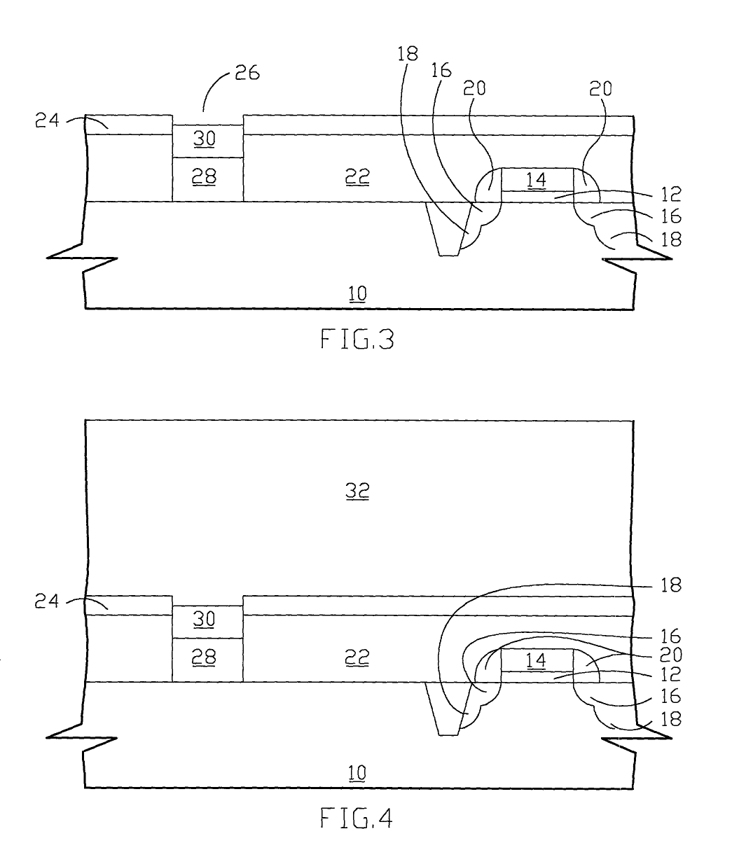

Then, referring to FIG. 3, a first patterned photoresist layer is formed on the SiN layer 24 and performing an etching process is performed to form a node-contact hole opening 26. Next, a polysilicon layer is deposited to fill with the node-contact hole opening 26 by conventional CVD (chemical vapor deposition) method. Thereafter, an etching-back process and a recessing process are sequentially performed to the polysilicon to form a recessed polysilicon 28 in the node-contact hole opening 26. Then, an oxidation-resistant barrier layer 30 is deposited by a reactive sputtering method on the recessed polysilicon 28 and SiN layer 24, wherein the material of oxidation-resistant barrier layer 30 can be TaN (tantalum nitride). In the present invention, the amorphous TaN has revealed an excellent barrier performance as an oxidation-resistant barrier layer.

The formation steps of the TaNₓ film are deposited by a reactive sputtering method from a Ta target in the mixture gases of N₂ (nitrogen)/Ar (argon), wherein the suffix x is stoichiometry. The ratio of N/Ta is controlled by the partial pressure of N₂ (P_{N2}). When the ratio of N/Ta is below 0.45, the TaNₓ film is poly-crystallized, and the thickness of TaNₓ is similar to the TiN (titanium nitride) layer that is increased by oxidation. It is thought that the oxygen diffusion via grain boundary of TaNₓ films such that the oxidation of the barrier layer will be enhanced.

Moreover, when the ratio of N/Ta is large than 0.45, an amorphous TaNₓ films can be obtained. In particular, when the ratio of N/Ta is between about 0.45 and 0.55, the very slight quantity of oxygen is detected at the surface. Furthermore, when the ratio of N/Ta is higher than 0.55, the TaNₓ films will be damaged and become porous with N₂ gas bubbles although in the amorphous state. In conclusion, when the suffix x is between about 0.45 and 0.55, the TaNₓ is an excellent oxygen diffusion barrier. Then, the diffusion barrier layer 30 is planarized and the portion of the diffusion barrier layer 30 is removed on the SiN layer 24 by a polishing method such as CMP (chemical mechanical polishing) method.

Next, referring to FIG. 4 to FIG. 5, a second ILD layer 32 is deposited on the structure of the FIG. 3 (shown in FIG. 4), and a photolithography process is performed to the second ILD layer 32 to form a storage node (SN) hole opening 34 (shown in FIG. 5) within the second ILD layer 32, and a portion of the SiN layer 24 and a diffusion barrier layer 30 being exposed.

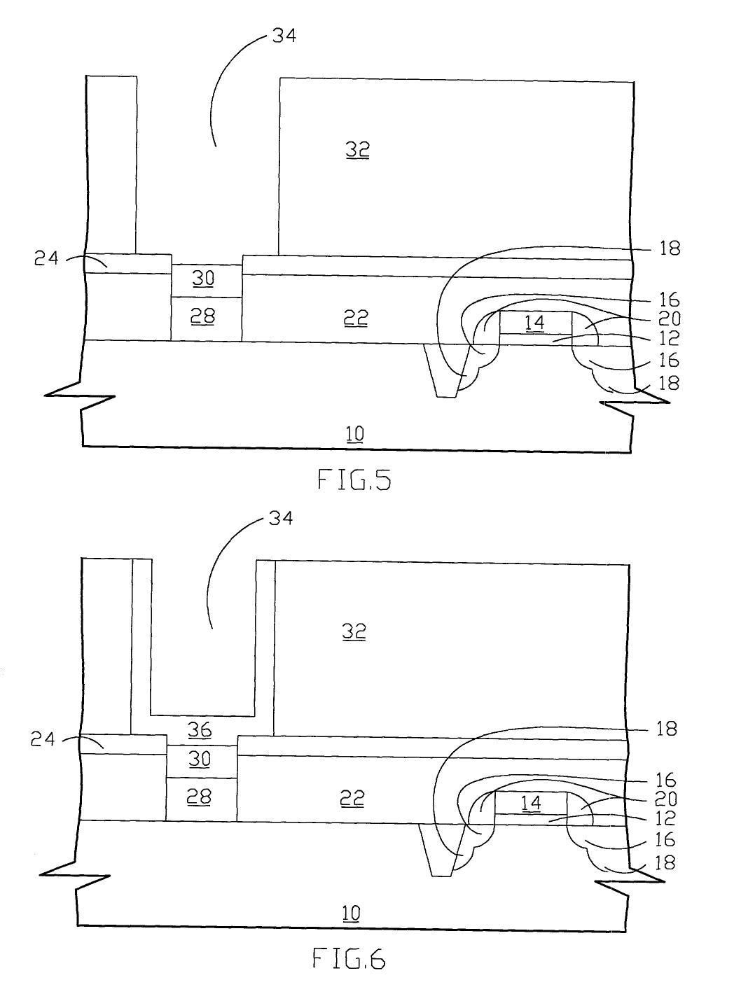

Thereafter, referring to FIG. 6, a first metal layer such as Ta—Ruₓ—N_{y} layer of MIM capacitor is deposited by CVD method to fill with the storage node (SN) hole opening 34, wherein the suffix x and y are stoichiomerty for Ru and N respectively. The advantage of the Ta—Ruₓ—N_{y} layer is that the suffix x is equal to 1 and y is between about 0.4 and 0.6, the Ta—Ruₓ—N_{y} layer 36 has a good thermal stability and oxygen diffusion barrier. (Ta—Ruₓ—N_{y} [symbol] [symbol] , [symbol] ) Then, the Ta—Ruₓ—N_{y} layer is etched back to form a first electrode (bottom electrode) 36 of MIM capacitor on the sidewall of the storage node (SN) hole opening 34.

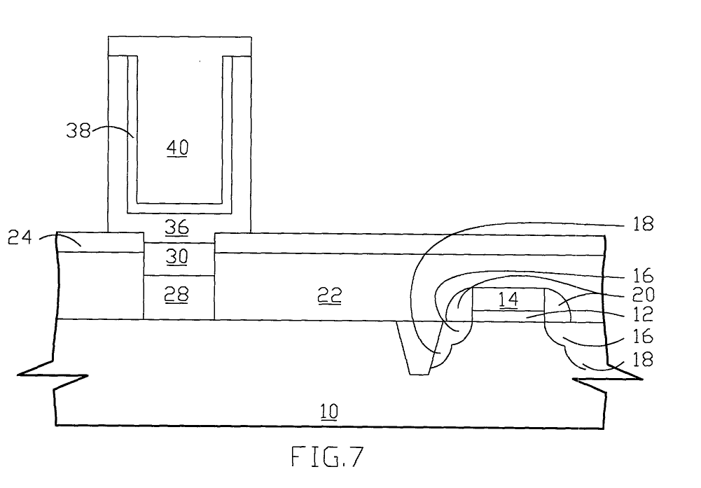

Next, referring to FIG. 7, after the second ILD layer 32 is removed, the dielectric layer as an insulator layer 38 of MIM capacitor is deposited by CVD method to form on the sidewall of the first electrode 36. The dielectric layer has dielectric constant higher than 10. The material of dielectric layer 20 such as Al-doped Zr-silicate ((Al₂O₃)ₓ.(ZrO₂)_{y}.(SiO₂)_{z}), hafnium dioxide (HfO₂), or tantalum pentoxide (Ta₂O₅), which are good candidates for high dielectric for their reasonable high dielectric constant, has low resistivity, good thermal stability, and chemical stability, wherein the suffix x, y, and z are stoichiomerty for Al₂O₃, ZrO₂, and SiO₂ respectively. Thereafter, in the present invention, in order to crystallize for insulator layer, an annealing treatment with temperature about 550° C. is performed to the insulator layer 38. Afterward, the second metal layer as second electrode 40 of MIM capacitor is deposited to fill with the storage node (SN) hole opening 34. The material of the second electrode 40 such as TaN or TiN.

The summary of the abovementioned, we can achieve the advantages as following:

Firstly, according to FIG. 3 to FIG. 6, the TaNₓ as an oxidation-resistant barrier layer can improve the prior oxygen ions through the Ru storage node beneath SN during the oxidation process, In particular, the TaNₓ has an excellent barrier property when the suffix x is between about 0.45 and 0.55. Therefore, the prior node resistance issue can be improved.

Secondly, according to FIG. 6, the material of first electrode is Ta—Ruₓ—N_{y} , when suffix x is equal to 1, y is between about 0.4 and 0.6, the Ta—Ruₓ—N_{y} has a good thermal stability and oxygen diffusion barrier properties.

Thirdly, according to FIG. 7, dielectric layer such as Al-doped Zr-silicate ((Al₂O₃)ₓ.(ZrO₂)_{y}.(SiO₂)_{z}), hafnium dioxide (HfO₂), or tantalum pentoxide (Ta₂O₅), which are good candidates for high dielectric for their reasonable high dielectric constant, has low resistivity, good thermal stability, and chemical stability. Therefore, the capacitance of MIM capacitor can increased and the reliability also can be increased.

Although specific embodiments have been illustrated and described, it will be obvious to those skilled in the art that various modifications may be made without departing from what is intended to be limited solely by the appended claims.

What is claimed is:

1. A method for forming a metal-insulator-metal capacitor, said method comprising steps of:
providing a substrate having a node contact hole opening within a first inter-layer dielectric layer thereon and a recessed polysilcion layer formed in said node contact hole opening;
forming an oxidation-resistant barrier layer on said recessed polysilicon layer;
forming a storage node hole opening within a second inter-layer dielectric layer, wherein said second inter-layer dielectric layer is on said substrate;
forming a first electrode on the sidewall of said storage node hole opening;
removing said second inter-layer dielectric layer;
forming an insulator layer on the first electrode; and
forming a second electrode on said insulator layer.

2. The method according to claim 1, wherein said step of forming said oxidation-resistant barrier layer comprises a reactive sputtering method.

3. The method according to claim 2, wherein the material of said oxidation-resistant barrier layer comprises tantalum nitride (TaNₓ).

4. The method according to claim 2, wherein the material of said first electrode comprises tantalum-ruthenium-nitrogen (Ta—Ruₓ—N_{y}).

5. The method according to claim 1, wherein the material of said insulator layer comprises a dielectric layer.

6. The method according to claim 5, wherein said dielectric layer is chosen from the group consisting of Al-doped Zr-silicate ((Al₂O₃)ₓ.(ZrO₂)_{y}.(SiO₂)_{z}), hafnium dioxide (HfO₂), and tantalum pentoxide (Ta₂O₅).

7. The method according to claim 1, wherein the material of said second electrode comprises a tantalum nitride (TaN).

8. The method according to claim 1, wherein the material of said second electrode comprises a titanium nitride (TiN).

9. A method for forming an oxidation-resistant structure, said method comprising steps of:
providing a substrate having a node contact hole opening within a first inter-layer dielectric layer thereon and a recessed polysilicon layer in said node contact hole opening;
reactive sputtering an oxidation-resistant barrier layer on the substrate;
removing the portion of said oxidation-resistant barrier layer on said substrate;
forming a storage node hole opening within a second inter-layer dielectric layer, wherein said second inter-layer dielectric layer on said substrate;
depositing a first metal layer in said storage node hole opening;
etching back said first metal layer to form a first electrode on the sidewall of said storage node hole opening;
removing said second inter-layer dielectric layer;
depositing an insulator layer on the sidewall of said first electrode; and
depositing a second metal layer to fill with said storage node hole opening.

10. The method according to claim 9, wherein the material of said oxidation-resistant barrier layer comprises a tantalum nitride (TaNₓ).

11. The method according to claim 9, wherein the material of said first metal layer comprises a tantalum-ruthenium-nitrogen (Ta—Ruₓ—N_{y}).

12. The method according to claim 9, wherein said insulator layer is chosen from the group consisting of Al-doped Zr-silicate ((Al₂O₃)ₓ.(ZrO₂)_{y}.(SiO₂)_{z}), hafnium dioxide (HfO₂), and tantalum pentoxide (Ta₂O₅).

13. The method according to claim 9, wherein the material of said second metal layer comprises a tantalum nitride (TaN).

14. The method according to claim 9, where the material of said second metal layer comprises a titanium nitride (TiN).

15. A method for forming an oxidation-resistant structure for a metal-insulator-metal capacitor in a dynamic random access memory device, said method comprising steps of:
providing a substrate, a node contact hole opening within a silicon nitride layer and a first inter-layer dielectric layer thereon;
forming a recessed polysilicon layer in said node contact hole opening;
reactive sputtering an oxidation-resistant barrier layer on said recessed polysilicon layer;
chemical mechanical polishing said oxidation-resistant barrier layer to remove the portion of said oxidation-resistant barrier layer on said substrate;
forming a storage node hole opening within a second inter-layer dielectric layer on said substrate;
forming a first electrode on sidewall of said storage node hole opening and covering the portion of said oxidation-resistant barrier layer;
forming a high dielectric constant layer on the sidewall of said first electrode; and
forming a second electrode on the insulator layer.

16. The method according to claim 15, wherein the material of said oxidation-resistant barrier layer comprises a TaNₓ.

17. The method according to claim 16, wherein the value of the suffix x is between about 0.45 and 0.55.

18. The method according to claim 15, wherein the material of said first electrode comprises a Ta—Ruₓ—N_{y}.

19. The method according to claim 18, wherein the value of the suffix x is equal 1 and suffix y is between about 0.4 and 0.6.

20. The method according to claim 15, wherein said high dielectric constant layer is chosen from the group consisting of Al-doped Zr-silicate ((Al₂O₃)ₓ.(ZrO₂)_{y}.(SiO₂)_{z}), hafnium dioxide (HfO₂), and tantalum pentoxide (Ta₂O₅).

21. The method according to claim 15, wherein the material of said second electrode comprises a tantalum nitride (TaN).

22. The method according to claim 15, wherein the material of said second electrode comprises a titanium nitride (TiN).
